(19) United States
(12) Patent Application Publication
(10) Pub. No.: US 2015/0102819 A1
(43) Pub. Date: Apr. 16, 2015

(54) LITHIUM-ION ENERGY STORE WITH MEASURING CELL AND METHODS FOR DETERMINING PROPERTIES OF THE LITHIUM-ION ENERGY STORE

(71) Applicant: Robert Bosch GmbH, Stuttgart (DE)

(72) Inventor: Stefan Butzmann, Schalksmühle (DE)

(21) Appl. No.: 14/512,674

(22) Filed: Oct. 13, 2014

(30) Foreign Application Priority Data
Oct. 14, 2013 (DE) 10 2013 220 716.6

(51) Int. Cl. G01R 31/36

(52) U.S. Cl. CPC G01R 31/3624; G01R 31/3648
USPC 324/433

(57) ABSTRACT

A lithium-ion energy store (1), comprising an electrode having a main section (2) and having a measuring section (3) electrically isolated from the main section, a counterelectrode (4) and a separator (5) between the electrode and the counterelectrode, wherein a measuring cell, which forms a part of the lithium-ion energy store, comprises the measuring section (3) of the electrode, a counterelectrode measuring section, which is situated opposite the measuring section (3) of the electrode in relation to the separator (5), and a section of the separator (5) that is arranged between the measuring sections (3) of the electrode and the counterelectrode.

### BACKGROUND OF THE INVENTION

The present invention relates to a lithium-ion energy store, a series circuit arrangement comprising a series circuit formed by a plurality of lithium-ion energy stores, and methods for measuring properties of the lithium-ion energy store and of the series circuit

Lithium-ion energy stores have a high cell voltage and a good ratio between stored energy and weight and are therefore very well suited to mobile applications. In particular, lithium-ion energy stores are used as rechargeable batteries for electrically operated vehicles. Lithium-ion energy stores are often produced in a wound design, a planar material being wound up which comprises two planar electrodes and a separator electrically isolating the electrodes from one another. The electrodes typically comprise a metal collector, which is preferably coated with an electrode material on both sides. Typically, aluminum foil is used as metal collector in the cathode electrode, and copper foil in the anode electrode. The separator between the electrodes is usually impregnated with an ion transport means that enables ions to pass through the separator.

Lithium-ion energy stores are known as batteries and rechargeable batteries. As rechargeable batteries, they are used for example in so-called battery direct inverters (BDI), which can generate currents or voltages having a virtually freely configurable profile from a multiplicity of individual cells of lithium-ion energy stores.

In the prior art it is known for the current output by a lithium-ion energy store to be measured by means of a multiplicity of different sensors, for example sensors with a shunt resistor or with Hall sensors. Besides measuring means for the direct current flow, a multiplicity of other sensors and/or theoretical models exist which can be used to detect properties of lithium-ion energy stores. For this purpose, typically by means of sensors a number of specific properties of the energy store are detected and the theoretical models are applied to the detected values in order in deduce the electrical properties or the state of the energy store.

EP 2442400 A1 discloses an electrochemical cell based on lithium technology having an internal reference electrode. The latter is embedded into the separator, such that a reference cell is formed between the reference electrode and each of the conventional electrodes of the cell. By determining properties of the two reference cells, which represent half-cells of the energy store, it is possible to obtain information about each of said half-cells and thus also about the entire energy store. In this case, either the current of the entire cell is measured or a state of the energy store is deduced by means of other parameters and theoretical models. Furthermore, the additional electrode introduced into the separator impedes the ion flow at this location and entails the risk of a short circuit of the electrodes.

### SUMMARY OF THE INVENTION

In the lithium-ion energy store according to the invention, at least one of anode and cathode is subdivided into a main section and into a measuring section. This results in a measuring cell and a main cell of the energy store. In this case, an electrode of the energy store is defined as the electrode comprising the main section and the measuring section, which are electrically isolated from one another. Typically, the measuring section is considerably smaller than the main section. A counterelectrode is situated opposite the electrode in relation to the separator and can act jointly for both electrodes. A part of the counterelectrode that is designated as counterelectrode measuring section is situated opposite the measuring electrode, while a part of the counterelectrode that is designated as counterelectrode main section is situated opposite the main electrode. The counterelectrode main section and the counterelectrode measuring section can be electrically isolated from one another. It is possible to use both the anode and the cathode as electrode, while correspondingly the cathode or the anode serves as counterelectrode. The separator can be provided as a single, continuous element both for the measuring cell and for the main cell, but it is likewise conceivable also to subdivide the separator, thus resulting in planar sections that are respectively assigned to the main section of the electrode and to the measuring section of the electrode.

The measuring cell comprises the measuring section of the electrode, a counterelectrode measuring section, which is situated opposite the measuring section of the electrode in relation to the separator, and a section of the separator that is situated between the measuring section of the electrode and the counterelectrode measuring section. A property of the energy store can be determined with the aid of the measuring cell in a simple and cost-effective manner. The main cell comprises the counterelectrode main section of the electrode and, analogously to the measuring cell, a counterelectrode main section situated opposite the main section of the electrode in relation to the separator, and a section of the separator that is situated between the counterelectrode main section of the electrode and the main section of the counterelectrode. The main cell delivers at least a large part of the energy from the lithium-ion energy store to the unit to be supplied. The main cell is usually considerably larger than the measuring cell, both with regard to the storage capacity of the energy store and with regard to the area of the electrode and of the counterelectrode. By way of example, the capacity of the main cell is at least ten times the capacity of the measuring cell. Correspondingly, the properties of the measuring cell which are area-related, such as, for instance, the current output capability, an energy content and the like, can be transferred from the measuring cell to the main cell by means of scaling with a factor of the area ratio of the two cells. Other, non-area-related properties of the energy store, such as, for instance, an ageing state or the like, can be transferred from the measuring cell to the main cell without scaling. During normal operation, the main cell outputs current for the application in which the energy store is used, and is recharged during charging operation. In order to keep the state of the cells the same, both can also apply to the measuring cell.

In one embodiment of the lithium-ion energy store, the latter is provided with a first measuring arrangement, which can be used to measure an internal resistance of the lithium-ion energy store. For this purpose, a voltage measuring means is connected to the measuring section of the electrode and to the counterelectrode in order to measure a differential voltage between these two potentials. The voltage measuring means can be realized by using e.g. a subtractor circuit with an operational amplifier. Alternatively, a microprocessor or the like can be used, which can measure two different potentials, for example with two different analog-to-digital converters or one analog-to-digital converter with a changeover switch connected upstream. In addition, a current source is connected between the measuring electrode and the counterelectrode and brings about a current flow through the measuring cell.

An advantage of this energy store is that it is provided with means that can be used to determine current and voltage through the measuring cell, such that the internal resistance of the energy store can be calculated therefrom. If said internal resistance is scaled with the area ratio between measuring electrode and main electrode, then the internal resistance can be extrapolated to the main electrode, for example in a microcontroller or the like or in a calculation device separate from the energy store. With the known internal resistance of the measuring cell, it is possible to calculate the internal resistance of the entire lithium-ion energy store. Advantageously, the current source can be dimensioned such that its performance suffices only for an energization of the measuring cell, but not for an energization of the main cell. Such a self-measuring energy store is cost-effective as a result.

In one development of the embodiment described above, the current source is embodied as a current source which can be switched on and off. As a result, it is possible to constrain a current flow only during a measurement of the differential voltage through the measuring cell. A microcontroller or the like can be connected to the output of a subtractor or comprise the measuring means for detecting the differential voltage, wherein at the same time an output of the microcontroller is connected to a control input of the current source, by means of which control input said current source can be switched on and off.

In a further embodiment of the lithium-ion energy store, the latter comprises a second measuring arrangement, which can be used to measure the performance of the energy store. For this purpose, a resistor device having a variable resistor and a fixed resistor connected in series is connected between the measuring electrode and the counterelectrode. The resistance value of the variable resistor can be varied, for example by the electrical influencing of a control input of the variable resistor, while the fixed resistor has an at least approximately fixed resistance value. In this embodiment, during a measurement of the performance, the variable resistor is adjusted automatically such that, owing to the load current, at least approximately a setpoint voltage, which preferably corresponds to a minimum voltage of the measuring cell, arises between the measuring terminal of the measuring section and the counterelectrode terminal of the counterelectrode. In addition, a voltage measuring means is connected to the fixed resistor in order to measure a voltage across the fixed resistor. This voltage serves as a raw value of the performance measurement and is interpreted further in order to deduce the performance of the lithium-ion energy store.

In one development of this embodiment, the variable resistor is a semiconductor resistor, for instance a field effect transistor or a bipolar transistor or the like, which is provided with a control input. The second measuring arrangement comprises an input at which a setpoint value can be input into the regulation, an electrical actual value input, into which the potential of the measuring electrode of the energy store passes, this potential being related to the same reference potential as the setpoint voltage, and an output connected to the control input of the variable resistor. An operational amplifier is preferably used as regulator. Alternatively, e.g. a digital regulator can also be used. In the latter case, the setpoint voltage can be represented by a numerical setpoint value. It is also conceivable to use a microcontroller or the like with an analog-to-digital converter and to connect the latter to the measuring electrode.

In a further embodiment of the lithium-ion energy store, the latter comprises a third measuring arrangement for measuring the impedance of the lithium-ion energy store. For this purpose, an AC current source is connected in each case by one of its terminals to the measuring electrode and the counterelectrode, such that the AC current source can bring about an AC current via the measuring cell. In addition, a respective terminal of an AC voltage measuring means is connected to the measuring electrode and to the counterelectrode, which AC voltage measuring means can measure the voltage across the measuring cell. Preferably, but not necessarily, the AC current source operates with a frequency at which the AC voltage measuring means measures as well. From the AC voltage and from the AC current it is possible to calculate an impedance of the measuring cell, which comprises for example an impedance and a phase shift between the AC current and the AC voltage.

In one development of the embodiment described above, the impedance not just of an individual lithium-ion energy store but of a plurality of lithium-ion energy stores connected in series is determined by means of a fourth measuring arrangement. For this purpose, a series circuit arrangement comprising a series circuit formed by lithium-ion energy stores is proposed. A lithium-ion energy store according to the invention is arranged at one end of the series. In the series circuit, anodes and cathodes of energy stores adjacent to one another are respectively connected to one another. In this case, an AC current source constrains a current flow through the entire series of lithium-ion energy stores, wherein it is connected at one end of the series circuit to a counterelectrode of the energy store arranged there and it is connected at the other end of the series circuit to the measuring electrode of the energy store according to the invention that is arranged there. The main electrode of the latter energy store is not connected to an electrode of the adjacent energy store. The terminals of the AC voltage measuring means are connected to the terminals of the AC current source connected to the energy store. The impedance of the entire series of energy stores can be determined in this way. As in the variant with an individual energy store, for this purpose the AC current is related to the AC voltage in a known manner. In particular, the series circuit can comprise a battery module, for instance a BDI. The impedance can be converted from the measuring cell to the main cell and/or to the entire energy store by means of the area ratio between the main section of the electrode and the measuring section of the electrode.

A further aspect of the invention proposes a method which can be used to measure the internal resistance of a lithium-ion energy store. The method is applied to a lithium-ion energy store comprising a first measuring arrangement as described above. In this case, firstly a current is output from the current source and, during the current flow, the voltage between the measuring terminal and the electrode terminal is measured by the voltage measuring means. The internal resistance of the measuring cell can be calculated from the current and the voltage. For this purpose, the measured voltage is divided by the current intensity of the current source. The internal resistance of the measuring cell thus determined is then extrapolated to the main cell by extrapolation with the aid of the ratio of the area of the main section to the area of the measuring section. These calculations can be carried out by means of a microcontroller, for example, which can additionally have an analog-to-digital converter that can be used to convert the measured voltage into numerical values. In one variant, moreover, the flowing of current from the current source can be initiated with an output of the microcontroller. The measured voltage can be generated by a subtractor circuit. The current intensity output by the current source is preferably fixedly predefined and flows upon the current source being switched on. For calculating the internal resistance, the microcontroller knows the current intensity of the current source. By way of example, said current intensity can be stored as a numerical value.

A further aspect of the invention proposes a method for measuring the performance of a lithium-ion energy store comprising a second measuring arrangement as described above. The method involves drawing current from the measuring cell, said current being adjusted by a resistance regulating device such that approximately a setpoint voltage arises across the measuring cell. In this case, the current from the measuring cell flows via the fixed resistor, inter alia, such that a voltage proportional to the current is present across said fixed resistor. Said current is proportional to the voltage across the fixed resistor. The current and the voltage measurable across the fixed resistor can be used as a measure of the performance of the energy store. The performance of the measuring cell can be extrapolated with aid of the area ratio of the main section to the measuring section.

Yet another aspect of the invention proposes a method for measuring the impedance of a lithium-ion energy store or of a series circuit arrangement comprising a plurality of lithium-ion energy stores. In this case, the lithium-ion energy store comprises a third measuring arrangement, or the series circuit comprises a fourth measuring arrangement, which are described above in each case. An AC current source constrains a current flow through either the lithium-ion energy store or through the series circuit formed by a plurality of lithium-ion energy stores, wherein the intensity of the current flow is known. The current flows in each case via a measuring electrode of an energy store according to the invention. Simultaneously with the current flow, an AC voltage measuring means measures an AC voltage across the lithium-ion energy store or the series circuit having a plurality of lithium-ion energy stores. The impedance of the lithium-ion energy store or of the series circuit arrangement is then determined from the AC voltage and the AC current, for example in a microcontroller or the like or in a central calculation unit for a plurality of energy stores. From the impedance, it is possible to deduce the states of the lithium-ion energy store or the lithium-ion energy stores in the series circuit, this being known in the prior art.

### BRIEF DESCRIPTION OF THE DRAWINGS

Exemplary embodiments of the invention are described in detail below with reference to the accompanying drawings. In the drawings:

FIG. 1 shows a schematic illustration of the construction of an energy store according to the invention;

FIG. 2a shows a circuit symbol of a first variant of the energy store according to the invention;

FIG. 2b shows a circuit symbol of a second variant of the energy store according to the invention;

FIG. 3 shows a schematic circuit diagram of an illustration of a circuit arrangement of a first embodiment of the invention;

FIG. 4 shows a schematic circuit diagram of a circuit arrangement of a second embodiment of the invention;

FIG. 5 shows a schematic circuit diagram of a circuit arrangement of a third embodiment of the invention; and

FIG. 6 shows a schematic circuit diagram of a circuit arrangement of a development of the circuit arrangement in FIG. 5.

### DETAILED DESCRIPTION

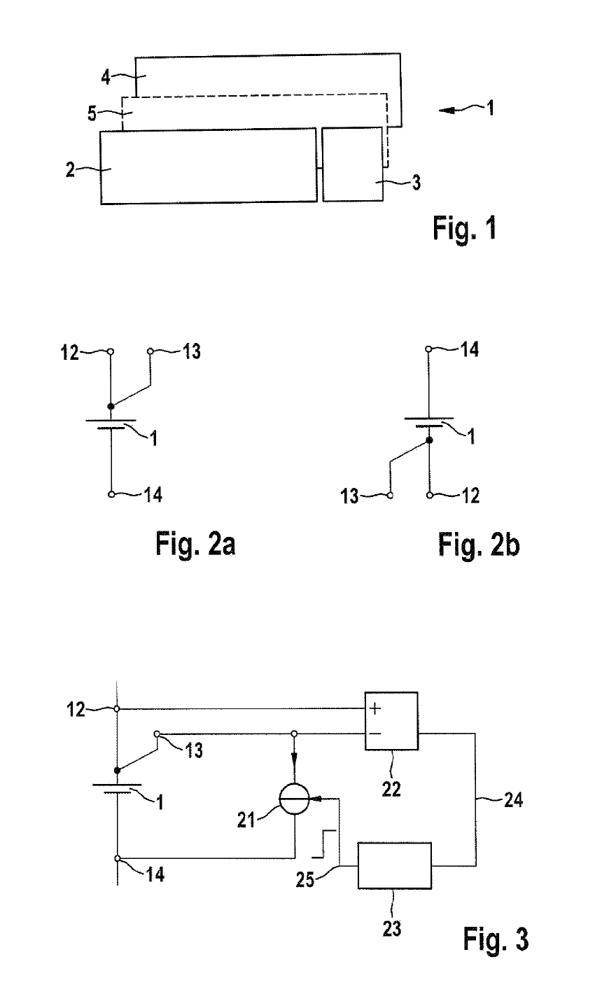

FIG. 1 schematically shows the construction of a lithium-ion energy store 1. The latter comprises an electrode 2, 3 subdivided into a main section 2 and a measuring section 3. The main section 2 and the measuring section 3 are electrically insulated from one another. The energy store furthermore comprises a separator 5 and a counterelectrode 4, wherein the separator 5 is arranged between the electrode 2, 3 and the counterelectrode 4 and prevents electrons from crossing between electrode and counterelectrode. In particular, the separator 5 lies between the measuring section 3 and the counterelectrode 4 and between the main section 2 and the counterelectrode 4. Preferably, the main section 2, the measuring section 3 and the counterelectrode 4 are provided in each case with a separate terminal for contact-connection. The terminals are not illustrated in FIG. 1. The electrode 2, 3 and the counterelectrode 4 are in each case a substantially planar structure. The main section 2 together with the counterelectrode 4 and the intervening section of the separator forms a main cell of the energy store. A measuring cell of the energy store is formed from the measuring section 3, the counterelectrode 4 and the section of the separator 5 that lies between these two elements. The electrode 2, 3 can be configured as an anode or as a cathode. The counterelectrode 4 is then the cathode in the first case, or the anode in the second case.

FIG. 2a shows a circuit symbol for the lithium-ion energy store 1. The energy store 1 itself is illustrated as a circuit symbol for a galvanic cell having the terminals 12, 13 and 14. In this case, the main section terminal 12 is connected to the main section 2 of the electrode 2, 3 and the measuring terminal 13 is connected to the measuring section 3 of the electrode 2, 3. The electrode 2, 3 is embodied as a cathode. The counterelectrode terminal 14 is connected to the counterelectrode 4 embodied as an anode.

FIG. 2b shows a further variant of the energy store 1 as a circuit symbol. In this example, the anode is embodied as a divided electrode 2, 3. The main section 2 is once again connected to the main section terminal 12, and the measuring section 3 to the measuring terminal 13. The counterelectrode 4 embodied as a cathode is connected to the counterelectrode terminal 14.

FIG. 3 schematically shows a circuit diagram of a circuit arrangement for measuring the impedance of an energy store 1. The measuring terminal 13 of the measuring electrode 3 is connected to one terminal of a current source 21. A second terminal of the current source 21 is connected to a terminal 14 of the counterelectrode 4, such that the current source 21 can bring about a current flow through the energy store 1. In this case, the current flows from a section of the counterelectrode 4 into the measuring electrode 3. The terminal 12 of the main electrode 2 is connected to one input of a differential amplifier 22. A further input of the differential amplifier 22 is connected to the measuring terminal 13 and one terminal of the current source 21. The output signal from the differential amplifier 22 thus corresponds to the potential difference between the main section 2 of the electrode 2, 3 and the measuring section 3 of the electrode 2, 3. Via a line 24, the output of the differential amplifier 22 is connected to an analog-to-digital converter input of a microcontroller 23. The microcontroller 23 knows the current intensity that flows through the current source 21 and the differential voltage of the potentials of the main section 2 and of the measuring section 3. In order to calculate an internal resistance of the energy store 1, the microcontroller 23 divides the differential voltage by the current intensity and thus obtains the internal resistance of the measuring cell. In order to extrapolate the internal resistance of the measuring cell to the main cell, the microcontroller divides the internal resistance of the measuring cell by an area ratio of the main section 2 to the measuring section 3. Said area ratio is stored in the microcontroller 23. The current source 21 is embodied as a switchable current source 21 that can be changed over between a current flow having a predefined intensity and no current flow. The current source 21 has a corresponding control input connected to a suitable output of the microcontroller 23 via the line 25. Consequently, the microcontroller 23 can carry out a measurement of the voltage if the current flow through the current source 21 is switched on. In quiescent operation of the measurement, the current source 21 is switched off. The calculation of the internal resistance can be carried out using the following formula:

$${R}_{i} = \frac{Δ U}{n ( {I}_{Measuring cell} )} ,$$

where Rᵢ denotes the internal resistance, n denotes the ratio of the area of the main section to the area of the measuring section, ΔU denotes the differential voltage and I_{Measuring cell} denotes the current through the measuring cell.

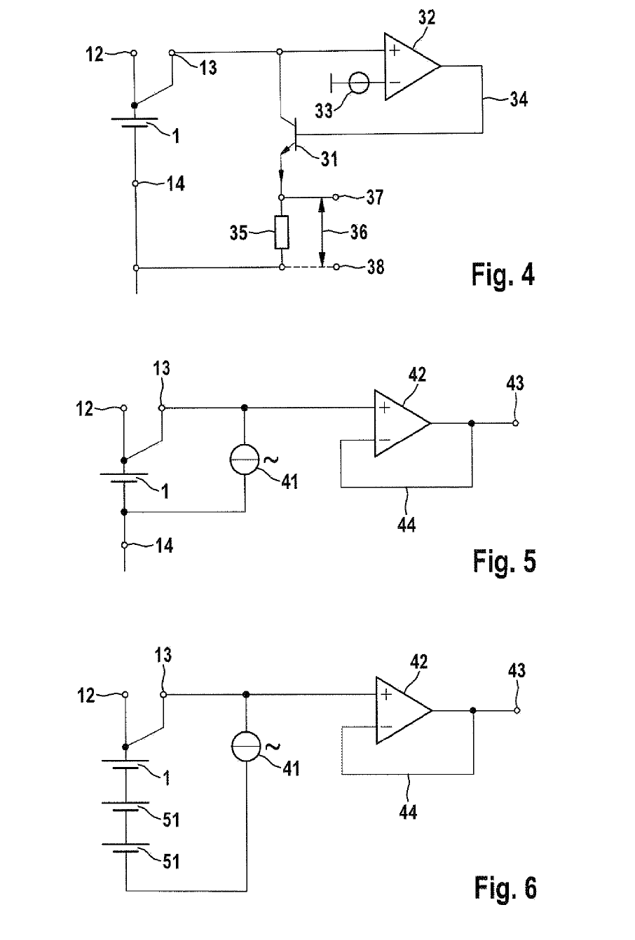

FIG. 4 schematically shows a circuit diagram of a circuit arrangement for measuring the performance of a lithium-ion energy store 1 according to the invention. A measuring arrangement is connected to the energy store 1, said measuring arrangement comprising a resistor device 31, 35 having a variable resistor 31 and a fixed resistor 35, which are connected in series. The variable resistor 31 is connected to the measuring terminal 13 of the energy store 1. The fixed resistor 35 is connected to the counterelectrode terminal 14 of the energy store 1. Alternatively, in one variant, the connections of the resistor device with respect to the terminals 13 and 14 can be embodied in an interchanged fashion in comparison with the variant described above. In addition, the positive input of an operational amplifier 32 is connected to the measuring terminal 13. The negative input of the operational amplifier 32 is connected to a setpoint voltage source 33. The differential signal between the setpoint voltage and the voltage at the measuring terminal 13 is conducted via the line 34 to a control input of the variable resistor 31. The variable resistor 31 is embodied as an NPN transistor. In this way, a control loop is realized which can be used to regulate the voltage at the measuring terminal 13 to the setpoint voltage. In this way, a current drawn from the measuring cell at the setpoint voltage flows via the resistor device 31, 35. Typically, the setpoint voltage is adjusted such that it corresponds to a minimum voltage, that is to say that the maximum possible current which still does not lead to destruction of the measuring cell is drawn from the measuring cell. A voltage 36 proportional to said current is dropped across the fixed resistor 35. Said voltage can be measured between the terminals 37 and 38 by a suitable voltage measuring means. The measurement result constitutes a value for the performance of the energy store 1.

FIG. 5 schematically shows a circuit diagram of a circuit arrangement for measuring the impedance of an energy store 1. A measuring arrangement comprising an AC current source 41 and an operational amplifier 42 connected as a voltage follower is connected to the energy store 1. The output of the operational amplifier 42 is fed back to the negative input thereof via the feedback line 44. The AC voltage source 41 is connected to the measuring terminal 13 by one of its terminals and to the counterelectrode terminal 14 by its other terminal. An AC current through the energy store 1 can be brought about by the AC current source 41. In this case, an alternating potential is established at the measuring terminal 13. This potential is impedance-converted by the voltage follower, such that a low-impedance output signal of the voltage follower is present at the terminal 43. The measurement of the potential at the measuring section 3 is preferably effected with reference to the counterelectrode 4, the potential of which can be tapped off at the counterelectrode terminal 14. The signal at the terminal 43 of the voltage follower is preferably read via an analog-to-digital converter into a microcontroller or the like, in which the current intensity of the current source 41 is additionally stored. Particularly preferably, such a microcontroller additionally detects the phase angle of the AC current, such that the microcontroller can calculate the impedance of the energy store 1 e.g. as impedance and phase rotation. This calculation can be carried out in the sense of electrical impedance spectroscopy, wherein the AC current I_{AC current}=ΔI·e^{i(ω-φ)} having the current amplitude ΔI flows as a consequence of the modulation voltage U_{AC current}=ΔU·e^{i(ω-φ)} having the voltage amplitude ΔU. In this case, ω is the frequency of the AC voltage and of the AC current and φ is the phase shift between the AC voltage and the AC current. The impedance Z of the measuring cell can be calculated using the following formula:

$$Z ( ω ) = \vert \frac{Δ U}{Δ I} \vert \cdot {e}^{i ϕ}$$

The impedance of the main cell can be derived from the impedance of the measuring cell by the impedance of the measuring cell being divided by the ratio of the area of the main cell to the area of the measuring cell.

FIG. 6 shows one development of the circuit arrangement from FIG. 5 as a schematic circuit diagram, by means of which the impedance of a plurality of lithium-ion energy stores 1, 51 can be measured simultaneously. In contrast to FIG. 5, rather than a single energy store 1, a series circuit formed by such an energy store 1 according to the invention with two further energy stores 51 is measured. In practice, a different number of further energy stores can also be measured. For this purpose, one terminal of the AC current source 41 is connected to the cathode of the energy store 51. The latter is arranged as the energy store 1 according to the invention at the other end of the series-connected energy stores 1, 51. As in FIG. 5, the other terminal of the AC current source 41 is connected to the measuring terminal 13 of the energy store 1 according to the invention. Consequently, the AC current source 41 can bring about a current through all the energy stores 1, 51 simultaneously, with the result that a potential representing the common impedance of the energy stores 1, 51 arises at the measuring terminal 13. Said potential is impedance-converted by a voltage follower, as in FIG. 5. The subsequent processing can likewise take place as described with reference to FIG. 5.

1. A lithium-ion energy store (1), comprising:
an electrode having a main section (2) and having a measuring section (3) electrically isolated from the main section;
a counterelectrode (4); and
a separator (5) between the electrode and the counterelectrode;
wherein a measuring cell, which forms a part of the lithium-ion energy store, comprises the measuring section (3) of the electrode, a counterelectrode measuring section, which is situated opposite the measuring section (3) of the electrode in relation to the separator (5), and a section of the separator (5) that is arranged between the measuring sections (3) of the electrode and the counterelectrode.

2. The lithium-ion energy store (1) according to claim 1, further comprising a first measuring arrangement for determining an internal resistance of the lithium-ion energy store (1), the first measuring arrangement including a voltage measuring device (22, 32, 42), for measuring a voltage between the measuring section (3) and the main section (2), connected to said measuring section and said main section and a current source connected to the measuring section (3) and to the counterelectrode (4).

3. The lithium-ion energy store (1) as claimed in claim 2, wherein the current source (21, 41) is a current source (21, 41) which can be switched on and off.

4. The lithium-ion energy store (1) as claimed in claim 1, comprising a second measuring arrangement for measuring the performance of the lithium-ion energy store, the second measuring arrangement including a resistor device (31, 35) comprising a variable resistor (31) having a variable resistance value and a fixed resistor (35) having a fixed resistance value in a series circuit connected between the measuring section (3) and the counterelectrode (4), wherein the variable resistor (31) is adjustable automatically in such a way that a setpoint voltage arises between the measuring section (3) and the counterelectrode (4), and a voltage measuring device is connected to two terminals (37, 38) of the fixed resistor in order to measure a voltage (36) across the fixed resistor (35).

5. The lithium-ion energy store (1) as claimed in claim 4, wherein the variable resistor (31) is a controllable semiconductor resistor having a control input, and the second measuring arrangement comprises a resistance regulating device (32), wherein the resistance regulating device (32) has a setpoint value input for a setpoint value corresponding to the setpoint voltage between the measuring section (3) and the counterelectrode (4), an electrical actual value input and an electrical output, wherein the actual value input is connected to the measuring section (3) and the output is connected to the control input of the semiconductor resistor (31).

6. The lithium-ion energy store (1) as claimed in claim 1, comprising a third measuring arrangement for detecting an impedance of the lithium-ion energy store (1), in which said measuring arrangement an AC current source (41) is connected to the measuring section (3) by one terminal and to the counterelectrode (4) by a further terminal, and an AC voltage measuring device is connected between the measuring section (3) and the counterelectrode (4).

7. A series circuit arrangement comprising a series circuit having a lithium-ion energy store (1) as claimed in claim 1 and at least one further lithium-ion energy store (51) and having a fourth measuring arrangement for detecting an impedance of the lithium-ion energy stores (1, 51) of the series circuit arrangement, wherein the series circuit arrangement an AC current source (41) is connected by one terminal to the measuring section (3) of a lithium-ion energy store at one end of the series circuit and is connected by a further terminal to the counterelectrode (4) of a lithium-ion energy store (1, 51) at an opposite end of the series circuit, and an AC voltage measuring device is connected to said measuring section (3) and said counterelectrode (4).

8. A method for measuring an internal resistance of a lithium-ion energy store (1) as claimed in claim 2, wherein the current source (21, 41) outputs a current, the voltage measuring device measures the voltage between the measuring section (3) and the main section (2), and the internal resistance is calculated by the measured voltage being divided by the current intensity of the current source and by a ratio of the area of the main section (2) to the area of the measuring section (3).

9. The method for measuring the performance of a lithium-ion energy store (1) as claimed in claim 4, wherein a current from the measuring cell is regulated by the resistance regulating device (32) in such a way that a setpoint voltage is established between the measuring section (3) and the counterelectrode (4), and a voltage (36) is measured across the fixed resistor (35) of the resistor device (31, 35), and said voltage (36) is used as a measure of the performance of the lithium-ion energy store (1).

10. The method for measuring the impedance of a series circuit arrangement (1, 51) as claimed in claim 7, wherein the AC current source (41) outputs an AC current that flows via the measuring section (3) and a counterelectrode (4), an AC voltage between the measuring section (3) and the counterelectrode (4) is measured, and the AC voltage is related to the AC current in order to determine the impedance of the lithium-ion energy store (1) or of the series circuit arrangement (1, 51).

11. The method for measuring the impedance of a lithium-ion energy store (1) as claimed in claim 6, wherein the AC current source (41) outputs an AC current that flows via the measuring section (3) and a counterelectrode (4), an AC voltage between the measuring section (3) and the counterelectrode (4) is measured, and the AC voltage is related to the AC current in order to determine the impedance of the lithium-ion energy store (1) or of the series circuit arrangement (1, 51).
